(19) United States
(12) Patent Application Publication
(10) Pub. No.: US 2015/0214075 A1
(43) Pub. Date: Jul. 30, 2015

(54) MANUFACTURING METHOD OF SELECTIVE ELECTRONIC PACKAGING DEVICE

(71) Applicant: UNIVERSAL SCIENTIFIC INDUSTRIAL (SHANGHAI) CO., LTD., SHANGHAI (CN)

(72) Inventors: JEN-CHUN CHEN, SHANGHAI (CN); SHIH-CHIEN CHEN, SHANGHAI (CN); PAI-SHENG CHENG, SHANGHAI (CN)

(73) Assignee: UNIVERSAL SCIENTIFIC INDUSTRIAL (SHANGHAI) CO., LTD., SHANGHAI (CN)

(21) Appl. No.: 14/246,114

(22) Filed: Apr. 6, 2014

(30) Foreign Application Priority Data
Jan. 24, 2014 (TW) 103102666

(51) Int. Cl. H01L 21/56

(52) U.S. Cl. CPC H01L 21/56

(57) ABSTRACT

A manufacturing method of selective electronic packaging device includes the following. A plurality of electronic components is disposed on a surface of a substrate. A photo-sensitive resin material is formed on the surface of the substrate. UV-light is irradiated to the photo-sensitive resin material to form an embankment structure. An encapsulating material is filled a protective area surrounded by the embankment structure. The encapsulating material covers at least one electronic component. The encapsulating material is solidified to form an encapsulating member, and the encapsulating member covers at least one electronic component.

### BACKGROUND

1. Technical Field

The present disclosure relates to a selective electronic packaging device and the manufacturing method thereof.

2. Description of Related Art

Most electronic packaging devices use encapsulating materials to package electronic components. Since electronic products have more and more functions, the type of electronic components in the electronic packaging devices corresponding increases as well. However, since all electronic components are packaged in one electronic packaging device by encapsulating material, it is hard to replace at least a failed electronic component while some of the electronic components fail. Or, some electronic packaging devices include optoelectronic elements which cannot be packaged in encapsulating materials.

Generally speaking, in order to replace the failed electronic component conveniently and increase the design agility, the electronic packaging devices usually are designed to having many encapsulating members to covers different electronic components respectively.

In the process of producing those encapsulating members to package different electronic components respectively, a variety of molds would be designed to produce many encapsulating members. However, it may increase manufacturing difficulty and costs.

### SUMMARY

The present disclosure relates to manufacturing method of selective electronic packaging device to improve the present manufacturing method.

An exemplary embodiment of the present disclosure illustrates a method of manufacturing selective electronic packaging device. The manufacturing method of selective electronic packaging device includes the following. A plurality of electronic components is disposed on a surface of a substrate. A photo-sensitive resin material is formed on the surface of the substrate. The UV-light is irradiated to the photo-sensitive resin material to form an embankment structure, and the embankment structure surrounds at least one electronic component. An encapsulating material is filled in the protective area surrounded by the embankment structure and covers at least one electronic component, and the embankment structure surrounds the encapsulating material. The encapsulating material is solidified to form an encapsulating member, and the encapsulating member covers at least one electronic component.

To sum up, the present disclosure provides a selective electronic packaging device manufacturing method. The photo-sensitive resin material is sprayed repeatedly and surrounds the electronic component which needs to be encapsulated. The UV-light is irradiated to the photo-sensitive resin material at the same time. Then, the photo-sensitive resin material is solidified to form the embankment structure. The encapsulating material is filled in the protective area surrounded by the embankment structure and then solidified to form the encapsulating member. The encapsulating member can cover the electronic component needs to be encapsulated. Hence, the design agility of the selective electronic packaging device increases.

In order to further understand the techniques, means and effects of the present disclosure, the following detailed descriptions and appended drawings are hereby referred, such that, through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1A depicts a vertical view diagram of a selective electronic packaging device in accordance with an exemplary embodiment of the present disclosure.

FIG. 1B depicts a section diagram of a selective electronic packaging device shown in FIG. 1A along a line P-P in accordance with an exemplary embodiment of the present disclosure.

FIGS. 2A to 2D depict section diagrams of manufacturing the selective electronic packaging device in each step in accordance with an exemplary embodiment of the present disclosure.

### DESCRIPTION OF THE EXEMPLARY EMBODIMENTS

Reference will now be made in detail to the exemplary embodiments of the present disclosure, examples of which are illustrated in the accompanying drawings. Wherever possible, the same reference numbers are used in the drawings and the description to refer to the same or like parts.

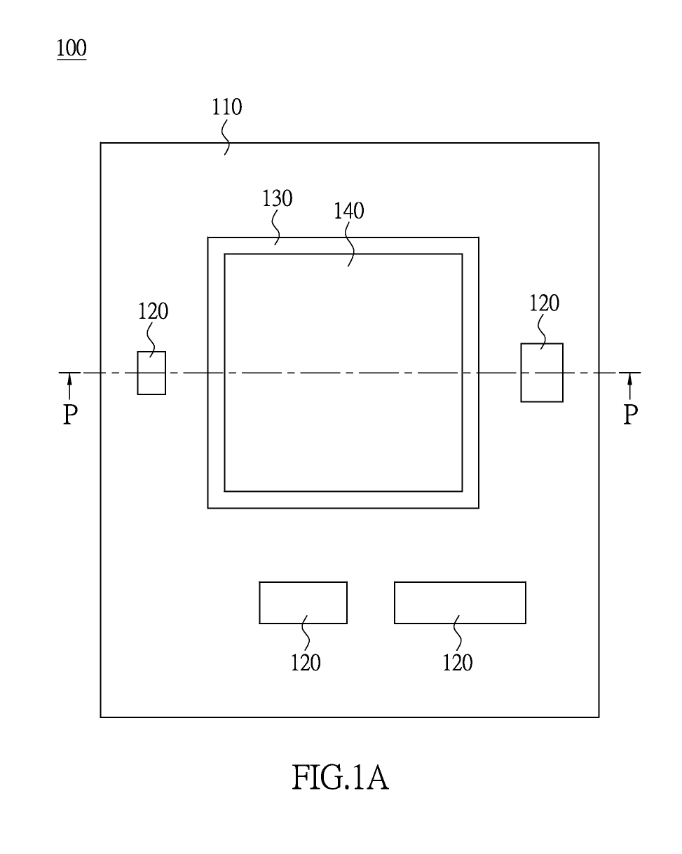

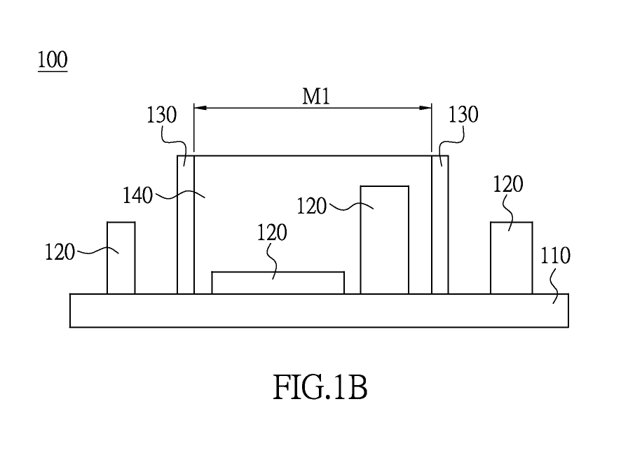

FIG. 1A illustrates a vertical view of a selective electronic packaging device in accordance to an exemplary embodiment of the present disclosure. FIG. 1B illustrates a section diagram of a selective electronic packaging device shown in FIG. 1A along a line P-P in accordance with an exemplary embodiment of the present disclosure. Please refer to FIGS. 1A and 1B. The selective electronic packaging device 100 includes a substrate 110, a plurality of electronic components 120 and an encapsulating member 140. The electronic components 120 are electrically connected to the substrate 110. The encapsulating member 140 covers some of the electronic components 120.

The substrate 110 is used to be a carrier for different electronic components 120. The substrate 110 can be a circuit substrate panel or a circuit substrate strip. The electronic components 120 can be active components or passive components, such as chips, transistors, diodes, capacitors, inductors, optoelectronics, or other high-frequency, RF components.

The electronic components 120 can be various. Namely, the types of the electronic components 120 are not the same. For example, one of the electronic components 120 can be diode, whereas the other electronic component 120 can be chip. As shown in FIGS. 1A and 1B, the types of the electronic components 120 can be various, and are not limited to the present disclosure.

The encapsulating member 140 can be a molding sealant to prevent unnecessary electrical connectivity, short circuiting, or the like. The encapsulating member 140 can be formed by solidifying an adhesive liquid encapsulating material, such as epoxy resin. Particularly, the encapsulating member 140 of the selective electronic packaging device 100 can package some of the electronic components 120 selectively. Hence, the electronic components 120 which need to be packaged can be covered by the encapsulating member 140 so as to increase design agility of the selective electronic packaging device 100.

In the embodiment, the selective electronic packaging device 100 may further include an embankment structure 130. The embankment structure 130 is in contact with and surrounds the encapsulating member 140. The embankment structure 130 encompasses a protective area Ml which needs to be encapsulated. The protective area Ml is defined as a region which will be packaged selectively, and the electronic components 120 which are packaged are disposed in the protective area Ml. The embankment structure 130 is made of photo-sensitive resin material. The photo-sensitive resin material solidifies in a polymerization by irradiation of the UV-light having specific wavelength.

The embankment structure 130 is needed during manufacturing the selective electronic packaging device. However, the embankment structure 130 of the selective electronic packaging device 100 can be removed or kept depending on product demand after the selective electronic packaging device 100 is complete. Hence, in other embodiment, the selective electronic packaging device 100 may not include the embankment structure 130. In addition, the selective electronic packaging device 100 can include an electromagnetic shielding layer (not shown) depending on product demand.

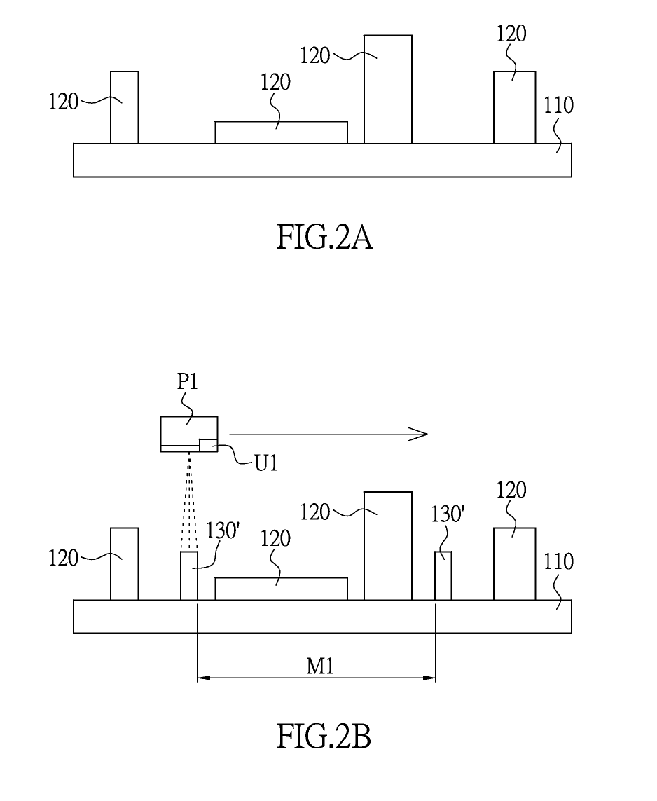

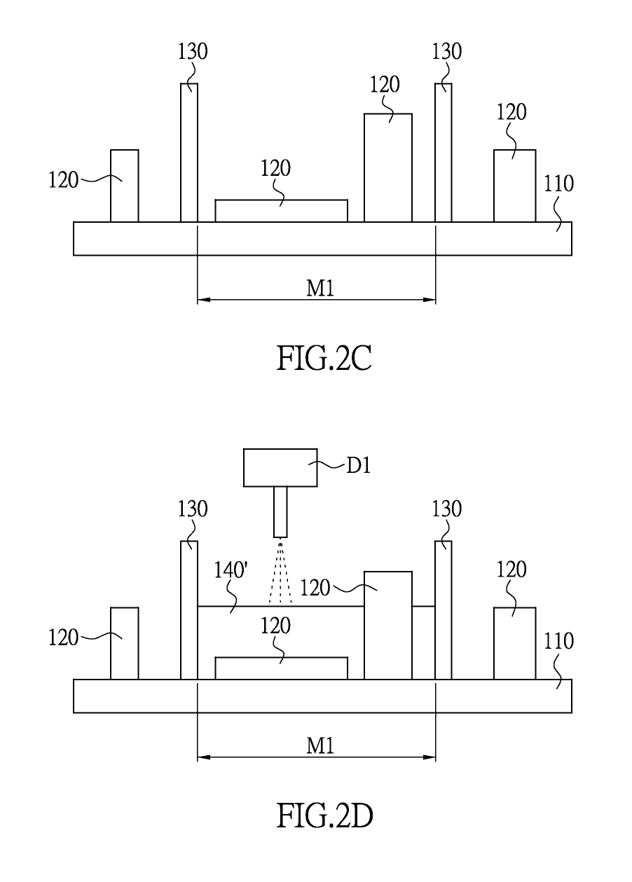

FIGS. 2A to 2D depict section diagrams of manufacturing the selective electronic packaging device in each step in accordance with an exemplary embodiment of the present disclosure. Please refer to FIG. 2A to 2D seriatim.

First, please refer to FIG. 2A. A plurality of electronic components 120 is disposed on a surface of the substrate 100. In practical, the substrate 110 can be a circuit substrate panel or a circuit substrate strip. The electronic components 120 can be chips, transistors, diodes, capacitors, inductors, optoelectronics, or other high-frequency, RF components. The electronic components 120 may be mounted to the substrate 110 by many ways, such as wire bonding, flip chip bonding, surface mount technology (SMT) or like. The ways that the electronic components 120 are mounted to the substrate 110 are not limited to the present disclosure

Please refer to FIG. 2B. The photo-sensitive resin material 130′ is sprayed on the surface of the substrate 110, and UV-light is irradiated to the photo-sensitive resin material 130′. Specifically, first, the photo-sensitive resin material 130′ is sprayed and surrounds at least one electronic component 120 by moving the spray-nozzle P1 to define the protective area Ml. The protective area Ml is a region which will be packaged by the encapsulating member 140 in the selective electronic packaging device 100, and the electronic component 120 which is packaged is disposed in the protective area M1. The photo-sensitive resin material 130′ is stacked up layer by layer by moving the spray-nozzle P1.

While the photo-sensitive resin material 130′ is sprayed through the spray-nozzle P1, the UV-light source U1 irradiates the UV-light to the photo-sensitive resin material 130′ at the same time. The photo-sensitive resin material 130′ is solidified immediately while the UV-light irradiates to the photo-sensitive resin material 130′. The photo-sensitive resin material 130′ is the resin which basically consists of polymer monomer, prepolymer and photosensitizer. The photo-sensitive resin material 130′ solidifies in a polymerization by irradiation of the UV-light having specific wavelength.

Please refer to FIG. 2C. While the photo-sensitive resin material 130′ is stacked up layer by layer, UV-light is irradiated to the photo-sensitive resin material 130′ at the same time. Hence, the photo-sensitive resin material 130′ solidifies. In the process of spraying the photo-sensitive resin material 130′ and irradiating UV-light repeatedly, the embankment structure 130 is formed and surrounds at least one electronic component 120. It is worth to notice that the embankment structure 130 surrounds protective area M1. In order to consider the height and arrangement of the electronic components 120, the height and shape of the embankment structure 130 can be various. For example, the shape of the embankment structure 130 can be a rectangular frame, a polygonal frame or an arbitrary shape frame. Namely, the embankment structure 130 is formed by moving the spray-nozzle P1 and spraying the photo-sensitive resin material 130′ to define the protective area Ml, then the height of the embankment structure 130 is adjusted according to the height of the electronic components 120 or product demand.

Please refer to FIG. 2D. An encapsulating material 140′ is filled in the protective area M1 surrounded by the embankment structure 130. Namely, the encapsulating material 140′ is filled in the protective area M1 surrounded by the embankment structure 130. Specifically, the encapsulating material 140′ is a liquid encapsulating material having good fluidity. The encapsulating material 140′ is filled in the protective area M1 surrounded by the embankment structure 130 through the dispenser D1 to cover the surface of the substrate 110, the electronic components 120 and the protective area M1. In the step of filling the encapsulating material 140′, the encapsulating material 140′ and the substrate 110 can be heated above room temperature under atmospheric pressure. In addition, the surface of the encapsulating material 140′ is substantially smooth, and the height of the filled encapsulating material 140′ approximates to the height of the embankment structure 130. The height of the encapsulating material 140′ is not limited to the present disclosure.

In the process of filling the encapsulating material 140′, the infiltration of air may generate bubbles. These bubbles may cause cavities in encapsulating member 140 or on outer surface of encapsulating member 140 and affect the quality of encapsulation. Hence, after the step of filling the encapsulating material 140′, the vacuum pressure and the environment temperature are raised and then maintained for 1 hour to release the bubbles in the encapsulating material 140′. The vacuum pressure is between 10⁻² ton and 10⁻³ torr, and the environment temperature is between 90° C. and 110° C., so as to release the bubbles from encapsulating material 140′.

Please refer to FIG. 1B again. The encapsulating material 140′ is solidified to form the encapsulating member 140, and the encapsulating member 140 covers at least one electronic component 120. Specifically, in the process of solidifying the encapsulating material 140′, the vacuum pressure is between 10⁻² ton and 10⁻³ ton, and the environment temperature is between 140° C. and 160° C. and then maintained for 3 hour. Hence, the encapsulating material 140′ is solidified to form the encapsulating member 140. The selective electronic packaging device 100 is finished substantially. The embankment structure 130 of the selective electronic packaging device 100 can be removed or kept depending on product demand. In addition, the selective electronic packaging device 100 can include an electromagnetic shielding layer depending on product demand.

In summary, the present disclosure provides a selective electronic packaging device manufacturing method. The photo-sensitive resin material is sprayed repeatedly and surrounds the electronic component which needs to be encapsulated. The UV-light is irradiated to the photo-sensitive resin material at the same time. Then, the photo-sensitive resin material is solidified to form the embankment structure. The encapsulating material is filled in the protective area surrounded by the embankment structure and then solidified to form the encapsulating member. The encapsulating member can cover the electronic component which needs to be encapsulated. Hence, the design agility of the selective electronic packaging device increases.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A method of manufacturing a selective electronic packaging device comprising:
disposing a plurality of electronic components on a surface of a substrate;
forming a photo-sensitive resin material on the surface of the substrate;
irradiating UV-light to the photo-sensitive resin material to form an embankment structure;
filling an encapsulating material in a protective area surrounded by the embankment structure, wherein the encapsulating material covers at least one electronic component; and
solidifying the encapsulating material to form an encapsulating member, wherein the encapsulating member covers at least one electronic component.

2. The method as recited in claim 1, wherein the photo-sensitive resin material is formed on the surface of the substrate by spraying.

3. The method as recited in claim 2, wherein the step of spraying the photo-sensitive resin material and irradiating UV-light to the photo-sensitive resin material are carried out at the same time.

4. The method as recited in claim 1, wherein the step of filling an encapsulating material is carried out under atmospheric pressure.

5. The method as recited in claim 1 further comprising:
releasing bubbles from the encapsulating material after the step of filling the encapsulating material.

6. The method as recited in claim 5, wherein the step of releasing bubbles from the encapsulating material comprises:
setting a vacuum pressure to release bubbles from the encapsulating material, wherein the vacuum pressure is between 10⁻² torr and 10⁻³ torr.

7. The method as recited in claim 5, wherein the step of releasing bubbles from the encapsulating material comprises:
setting the environment temperature between 90° C. and 110° C.

8. The method as recited in claim 1, wherein the step of solidifying the encapsulating material is carried out under the pressure from 10⁻² torr to 10⁻³ torr and the environment temperature between 140° C. and 160° C.
